(19) United States
(12) Patent Application Publication
(10) Pub. No.: US 2026/0314403 A1
(43) Pub. Date: Oct. 8, 2026

(54) CREATING A SINTERING METALLIZATION LAYER ON EXPOSED SURFACES OF SILICON DIES FOR DSMBGAS TO ENHANCE HEAT DISSIPATION

(71) Applicant: Qorvo US, Inc., Greensboro, NC (US)

(72) Inventor: Zhengpeng Xiong, Singapore (SG)

(21) Appl. No.: 19/545,526

(22) Filed: Feb. 20, 2026

Related U.S. Application Data
(60) Provisional application No. 63/783,294, filed on Apr. 4, 2025.

(51) Int. Cl. H10W 40/20; H10P 52/00; H10W 40/25; H10W 70/05; H10W 70/60; H10W 72/00; H10W 72/30; H10W 74/10; H10W 90/00; H10W 90/10; H10W 90/20; H10W 90/22

(52) U.S. Cl. CPC H10W 40/242; H10P 52/00; H10W 40/258; H10W 70/099; H10W 70/611; H10W 72/01304; H10W 72/01323; H10W 72/01361; H10W 72/322; H10W 72/352; H10W 72/365; H10W 72/877; H10W 74/117; H10W 90/10; H10W 90/22; H10W 90/288; H10W 90/291; H10W 90/724; H10W 90/7295; H10W 90/734

(57) ABSTRACT

Embodiments of a radio frequency (RF) package and methods of manufacturing the same are disclosed. In one embodiment, the RF package includes a package substrate, at least one semiconductor die, and an overmold. The package substrate has a side, and the semiconductor die is mounted to the side of the substrate. The semiconductor die includes a semiconductor substrate, wherein the semiconductor substrate defines a substrate surface. The overmold covers the side of the package substrate while the substrate surface of the semiconductor substrate is exposed through the overmold. A sintering metallization layer is attached to the substrate surface of the semiconductor substrate and is exposed through the overmold. The sintering metallization layer may be soldered to a printed circuit board to improve heat dissipation for the semiconductor die in the RF package.

### RELATED APPLICATIONS

This application claims the benefit of provisional patent application Ser. No. 63/783,294, filed Apr. 4, 2025, the disclosure of which is hereby incorporated herein by reference in its entirety.

### FIELD OF THE DISCLOSURE

This disclosure relates generally to radio frequency packages and methods of manufacturing the same.

### BACKGROUND

Heat generated by semiconductor dies in radio frequency (RF) packages poses significant challenges for modern RF circuits. As chip designs become more complex and densely packed, thermal management has become a critical issue. Excessive heat can lead to performance degradation, reduced reliability, and shortened lifespan of the RF packages. High temperatures cause increased leakage currents in transistors, affecting signal propagation and potentially disrupting normal chip function. Thermal cycling due to temperature fluctuations can induce mechanical stress, compromising the structural integrity of the RF package and leading to fatigue and deterioration over time. These thermal challenges necessitate innovative cooling solutions and careful consideration of package design to ensure optimal performance and longevity of RF circuitry.

### SUMMARY

Embodiment 1. A radio frequency (RF) package, including: a package substrate having a side; a semiconductor die mounted to the side of the package substrate, the semiconductor die including a semiconductor substrate, wherein the semiconductor substrate defines a substrate surface; an overmold that covers the side of the package substrate, wherein the substrate surface of the semiconductor substrate is exposed through the overmold; a sintering metallization layer attached to the substrate surface of the semiconductor substrate is exposed through the overmold.

Embodiment 2. The RF package of embodiment 1, further including: a plurality of solder balls attached to the side of the package substrate, wherein the plurality of solder balls is exposed through the overmold.

Embodiment 3. The RF package of embodiment 1, wherein the sintering metallization layer is contiguous.

Embodiment 4. The RF package of embodiment 1, wherein the sintering metallization layer is patterned into sintering metallization patches.

Embodiment 5. The RF package of embodiment 4, wherein the sintering metallization patches are positioned in an array.

Embodiment 6. The RF package of embodiment 1, wherein the sintering metallization layer includes a sintering silver layer.

Embodiment 7. The RF package of embodiment 1, wherein the side of the package substrate is a first side of the package substrate, the overmold is a first overmold, and the semiconductor die is a first semiconductor die, and wherein: the RF package further includes a second semiconductor die and a second overmold; the package substrate defines a second side opposite the first side; the second semiconductor die is mounted to the second side of the package substrate; and the second overmold covers the second side of the package substrate.

Embodiment 8. A method of manufacturing an RF package, including: providing a package substrate defining a side, wherein a semiconductor die is attached to the side, the semiconductor die has a semiconductor substrate, wherein the semiconductor substrate defines a substrate surface, and an overmold covers the side and the semiconductor die including the semiconductor substrate; grinding through the overmold and the semiconductor substrate to thin the semiconductor substrate such that a surface of the semiconductor die is exposed through the overmold after the grinding; applying a metallization paste to the exposed surface of the semiconductor die; curing the metallization paste to form a sintering metallization layer attached to the substrate surface of the semiconductor substrate exposed through the overmold.

Embodiment 9. The method of embodiment 8, further including: applying a mask on the overmold after grinding, wherein the exposed surface of the semiconductor die is also exposed through the mask.

Embodiment 10. The method of embodiment 8, wherein apply the metallization paste to the exposed surface of the semiconductor die further includes patterning the metallization paste.

Embodiment 11. The method of embodiment 10, wherein the metallization paste is patterned into patches.

Embodiment 12. The method of embodiment 11, wherein the patches are positioned in an array.

Embodiment 13. The method of embodiment 9, further including: a plurality of solder balls are attached to the side of the package substrate, wherein the plurality of solder balls are exposed through the overmold.

Embodiment 14. The RF package of embodiment 9, wherein the side of the substrate package is a first side of the substrate package, the overmold is a first overmold, and the semiconductor die is a first semiconductor die, and wherein: the RF package further includes a second semiconductor die and a second overmold; the package substrate defines a second side opposite the first side; the second semiconductor die is mounted to the second side of the package substrate; and the second overmold covers the second side of the package substrate.

Embodiment 15.The RF package of embodiment 1, wherein the metallization paste includes a silver paste.

Embodiment 16. A user element that includes a radio frequency (RF) package including: a package substrate having a side; a semiconductor die mounted to the side of the package substrate, the semiconductor die including a semiconductor substrate, wherein the semiconductor substrate defines a substrate surface; an overmold that covers the side of the package substrate, wherein the substrate surface of the semiconductor substrate is exposed through the overmold; and a sintering metallization layer attached to the substrate surface of the semiconductor substrate is exposed through the overmold.

Embodiment 17. The user element of embodiment 16, wherein RF package further includes: a plurality of solder balls are attached to the side of the package substrate, wherein the plurality of solder balls is exposed through the overmold.

Embodiment 18. The user element of embodiment 16, wherein the sintering metallization layer is contiguous.

Embodiment 19. The user element of embodiment 16, wherein the sintering metallization layer is patterned into sintering metallization patches.

Embodiment 20. The user element of embodiment 19, wherein the sintering metallization patches are positioned in an array.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1A and FIG. 1B illustrate an embodiment of a radio frequency (RF) package, in accordance with some embodiments.

FIGS. 2A-2G illustrate procedures for manufacturing the RF package shown in FIG. 1A and FIG. 1B, in accordance with some embodiments.

FIG. 3 is the RF package mounted to a PCB, in accordance with some embodiments.

FIG. 4 is a user element, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

Embodiments of radio frequency (RF) packages and methods of manufacturing the same are disclosed. The RF packages have surfaces of semiconductor dies exposed through overmolds. A sintering metallization layer is attached to each of the exposed surfaces. In this manner, when the RF packages are mounted to printed circuit boards (PCBs), heat from the semiconductor dies with the sintering metallization layers can dissipate heat through the sintering metallization layers to the PCB. Therefore, the temperature of semiconductor dies in the RF package is reduced during operation, which benefits product performance and reliability.

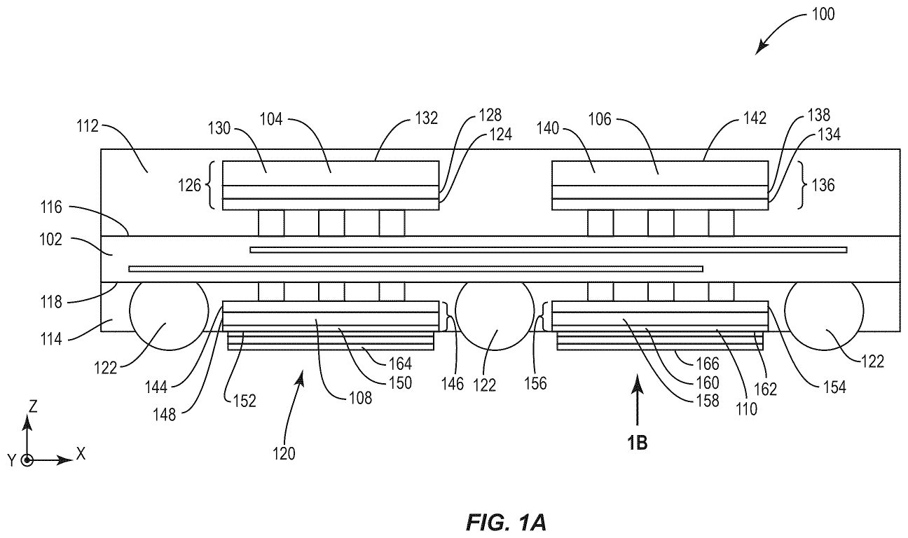

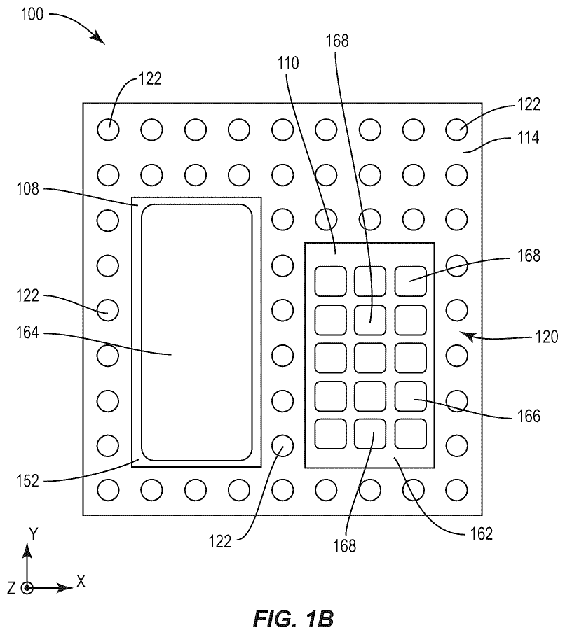

FIG. 1A and FIG. 1B illustrate an embodiment of a radio frequency (RF) package 100, in accordance with some embodiments. In particular, FIG. 1A is a cross-sectional view of the RF package 100, in accordance with some embodiments. FIG. 1B is a bottom view of the RF package 100 as shown looking into a direction 1B (shown in FIG. 1A), in accordance with some embodiments.

The RF package 100 includes a package substrate 102, semiconductor dies 104, 106, 108, 110, an upper overmold 112, and a lower overmold 114. When discussing the RF package 100, a Z-axis is defined with respect to the direction of stacking different components in the RF package 100. For example, the semiconductor dies 104, 106 are stacked over the package substrate 102, and the semiconductor dies 108, 110 are stack under the package substrate 102. (It should be noted that the terms “over” and “under” here are arbitrary and are simply used to reference displacement along the Z-axis in different directions). The Z-axis thus defines vertical directions with respect to the RF package 100. An X-axis defines a first horizontal axis while a Y-axis defines a second horizontal axis with respect to the RF package 100. The Z-axis, the X-axis, and the Y-axis are all orthogonal with respect to one another.

The package substrate 102 may have a body made from a laminate (e.g., fiberglass or reinforced epoxy resin), ceramics (e.g., aluminum oxide or aluminum nitride), polyimide-based materials, and/or the like. The package substrate 102 further includes a conductive structure that provides routing for different signals, passive electronic components (e.g., capacitors, inductors), and input/output terminals for receiving and transmitting signals externally into and out of the RF package 100.

The RF package 100 shown in FIG. 1A is a double-sided molded ball grid array (DSMBGA). Accordingly, the package substrate 102 includes at least one semiconductor die (e.g., semiconductor dies 104, 106) mounted on a upper side 116 of the RF package 100 and at least one semiconductor die (e.g., semiconductor dies 108, 110) mounted to a lower side 118 of the package substrate 102, wherein the lower side 118 is opposite the upper side 116 with respect to the Z-axis. In FIG. 1A, the semiconductor die 104 and the semiconductor die 106 are mounted to the upper side 116 while the semiconductor die 108 and the semiconductor die 110 are mounted to the lower side 118. It should be noted that other embodiments of the RF package 100 may not be double-sided but rather may be single-sided.

Furthermore, from a lower side 120 of the RF package 100, the RF package includes an array of solder balls 122 (not all labeled for the sake of clarity). The solder balls 122 connect to the conductive structure of the package substrate 102 to receive and transmit signals external to the RF package 100. As shown in FIG. 1A and FIG. 1B, the solder balls 122 are exposed externally from the RF package 100 from the lower side 120. It should be noted that other embodiments of the RF package 100 include dual in-line package (DIP), single in-line package (SIP), pin grid array (PGA), small outline package (SOP), thin small outline package (TSOP), quad flat package (QFP), plastic leaded chip carrier (PLCC), ceramic leadless chip carrier (CLCC), chip-scale package (CSP), system-in-package (SiP), multi-chip module (MCM), 3D packaging, transistor outline packages (TO-XX), zig-zag in-line package (ZIP), and any other suitable type of RF package.

The semiconductor die 104 includes a back-end-of line (BEOL) portion 124. The BEOL portion refers to the portion of a semiconductor die where interconnect layers are formed to connect different active semiconductor components and passive components in the semiconductor die and form an integrated circuit. BEOL processes are used to form the BEOL portion. The semiconductor die 104 further includes a semiconductor substrate 126. The semiconductor substrate 126 is formed from a semiconductor material such as silicon, gallium arsenide, silicon carbide, indium phosphide, germanium, and/or the like. The semiconductor substrate 126 includes a front-end-of line (FEOL) portion 128 and a handle 130. A FEOL portion includes one or more active semiconductor layers with active regions for the active semiconductor components and at least one metal layer where contacts for the active semiconductor components are formed. A handle is made of the semiconductor material and provides mechanical support for the FEOL portion. It should be noted that the semiconductor die 104 may include other structures and layers. A substrate surface 132 is defined by the handle 130 opposite an opposite side of the semiconductor die 104 from the external connectors of the BEOL portion 124.

The FEOL portion 128 may form a variety of active semiconductor components. The active semiconductor components in the FEOL portion 128 in combination with the connections provided by the BEOL portion 124 may form a variety of different RF circuitry such as power amplifiers, low-noise amplifiers, RF switching circuitry, power regulation circuitry, digital circuitry, and any other integrated circuit component that may be utilized for an RF circuit.

The BEOL portion 124 includes external connectors that allow for signals to be received and transmitted externally to and from the semiconductor die 104. The external connectors of the BEOL portion 124 are connected to the conductive structure on the upper side 116 of the package substrate 102.

The semiconductor die 106 includes a BEOL portion 134. The semiconductor die 106 further includes a semiconductor substrate 136. The semiconductor substrate 136 is formed from a semiconductor material such as silicon, gallium arsenide, silicon carbide, indium phosphide, germanium, and/or the like. The semiconductor substrate 136 includes a FEOL portion 138 and a handle 140. It should be noted that the semiconductor die 106 may include other structures and layers. A substrate surface 142 is defined by the handle 140 opposite an opposite side of the semiconductor die 106 from the external connectors of the BEOL portion 134.

The FEOL portion 138 may form a variety of active semiconductor components. The active semiconductor components in the FEOL portion 138 in combination with the connections provided by the BEOL portion 134 may form a variety of different RF circuitry such as power amplifiers, low-noise amplifiers, RF switching circuitry, power regulation circuitry, digital circuitry, and any other integrated circuit component that may be utilized for an RF circuit.

The BEOL portion 134 includes external connectors that allow for signals to be received and transmitted externally to and from the semiconductor die 106. The external connectors of the BEOL portion 134 are connected to the conductive structure on the upper side 116 of the package substrate 102.

The semiconductor die 108 includes a BEOL portion 144. The semiconductor die 108 further includes a semiconductor substrate 146. The semiconductor substrate 146 is formed from a semiconductor material such as silicon, gallium arsenide, silicon carbide, indium phosphide, germanium, and/or the like. The semiconductor substrate 146 includes a FEOL portion 148 and a handle 150. It should be noted that the semiconductor die 108 may include other structures and layers. A substrate surface 152 is defined by the handle 150 opposite an opposite side of the semiconductor die 108 from the external connectors of the BEOL portion 144.

The FEOL portion 148 may form a variety of active semiconductor components. The active semiconductor components in the FEOL portion 148 in combination with the connections provided by the BEOL portion 144 may form a variety of different RF circuitry such as power amplifiers, low-noise amplifiers, RF switching circuitry, power regulation circuitry, digital circuitry, and any other integrated circuit component that may be utilized for an RF circuit.

The BEOL portion 144 includes external connectors that allow for signals to be received and transmitted externally to and from the semiconductor die 108. The external connectors of the BEOL portion 144 are connected to the conductive structure on the lower side 118 of the package substrate 102.

The semiconductor die 110 includes a BEOL portion 154. The semiconductor die 110 further includes a semiconductor substrate 156. The semiconductor substrate 156 is formed from a semiconductor material such as silicon, gallium arsenide, silicon carbide, indium phosphide, germanium, and/or the like. The semiconductor substrate 156 includes a FEOL portion 158 and a handle 160. It should be noted that the semiconductor die 110 may include other structures and layers. A substrate surface 162 is defined by the handle 160 opposite an opposite side of the semiconductor die 110 from the external connectors of the BEOL portion 154.

The FEOL portion 158 may form a variety of active semiconductor components. The active semiconductor components in the FEOL portion 158 in combination with the connections provided by the BEOL portion 154 may form a variety of different RF circuitry such as power amplifiers, low-noise amplifiers, RF switching circuitry, power regulation circuitry, digital circuitry, and any other integrated circuit component that may be utilized for an RF circuit.

The BEOL portion 154 includes external connectors that allow for signals to be received and transmitted externally to and from the semiconductor die 108. The external connectors of the BEOL portion 154 are connected to the conductive structure on the lower side 118 of the package substrate 102.

The upper overmold 112 covers the upper side 116 of the package substrate 102. In this embodiment, the upper overmold 112 further covers the semiconductor die 104 and the semiconductor die 106 including the substrate surface 132 and the substrate surface 142. The upper overmold 112 may be formed from a thermoset epoxy or a thermoplastic material. The upper overmold 112 protects the package substrate 102 and the semiconductor dies 104, 106 from physical damage, environmental factors, and electromagnetic noise. The upper overmold 112 encapsulates the upper side 116 of the package substrate 102, the semiconductor die 104, and the semiconductor die 106. In this embodiment, the semiconductor die 104 and the semiconductor die 106 are entirely encapsulated by the upper overmold 112.

The lower overmold 114 covers the lower side 118 of the package substrate 102. In this embodiment, the lower overmold 114 partially covers the semiconductor die 108 and the semiconductor die 110. In particular, the lower overmold 114 does not cover the substrate surface 152 and the substrate surface 162. Thus, the substrate surface 152 of the semiconductor die 108 and the substrate surface 162 of the semiconductor die 110 are exposed through the lower overmold 114. The lower overmold 114 may be formed from a thermoset epoxy or a thermoplastic material. The lower overmold 114 protects the package substrate 102 and the semiconductor dies 108, 110 from physical damage, environmental factors, and electromagnetic noise. The lower overmold 114 encapsulates the lower side 118 of the package substrate 102 and partially encapsulates the semiconductor die 108 and the semiconductor die 110.

A sintering metallization layer 164 is attached to the substrate surface 152 of the handle 150 of semiconductor substrate 146. The sintering metallization layer 164 is exposed through the lower overmold 114. A sintering metal is formed from metal particles that have been compacted and heated to a temperature below the melting point of metal to fuse together the metal particles without melting the metal particles to the point of liquification. The heat and compaction fuse the metal into a dense bulk. The sintering metallization layer 164 can be connected to a PCB (not shown in FIG. 1A and FIG. 1B) through a metallurgical solder joint in a board-level assembly process after applying solder paste and reflow-soldering. The solder joint formed with the sintering metallization layer 164 acts as a direct heat-dissipation path from semiconductor die 108 to a PCB because of its thermally conductive nature (e.g., the thermal conductivity of a solder SAC305 (tin/silver/copper alloy 305) alloy is ~50 W/m·K). Therefore, the temperatures of the semiconductor die 108 and the other semiconductor dies 104, 106, 110 on the package substrate 102 are reduced during operation, which benefits product performance and reliability.

In this embodiment, the sintering metallization layer 164 is formed from a sintering silver layer. In other embodiments, the sintering metallization layer 164 may be any other type of metal that is sinterable such as tungsten, molybdenum, gold, tin, copper, aluminum, nickel, sinterable alloys, and/or the like. In FIG. 1B, the sintering metallization layer 164 is contiguous and may be spread relatively evenly across the substrate surface 152.

A sintering metallization layer 166 is attached to the substrate surface 162 of the handle 160 of semiconductor substrate 156. The sintering metallization layer 166 is exposed through the lower overmold 114. The sintering metallization layer 166 can be connected to a PCB (not shown in FIG. 1A and FIG. 1B) through a metallurgical solder joint in a board-level assembly process after applying solder paste on the PCB and reflow-soldering. The solder joint formed with the sintering metallization layer 166 acts as a direct heat-dissipation path from semiconductor die 110 to a PCB because of its thermally conductive nature (e.g., the thermal conductivity of a solder SAC305 (tin/silver/copper alloy 305) alloy is ~50 W/m·K). Therefore, the temperatures of semiconductor die 110 and other semiconductor dies 104,106, 108 on the package substrate 102 are reduced during operation, which benefits product performance and reliability.

In this embodiment, the sintering metallization layer 166 is formed from a sintering sliver layer. In other embodiments, the sintering metallization layer 166 may be any other type of metal that is sinterable such as tungsten, molybdenum, gold, tin, copper, aluminum, nickel, sinterable alloys, and/or the like. In FIG. 1B, the sintering metallization layer 166 is patterned into sintering metallization patches 168 (as shown in FIG. 1B; not all labeled for the sake of clarity). In particular, the sintering metallization patches 168 are patterned into an array, which in this embodiment has rows and columns of the sintering metallization patches 168. The sintering metallization patches 168 shown in FIG. 1B have a square cross-section. Other embodiments of the sintering metallization patches 168 may have any suitable shape including irregular shapes. The sintering metallization layers 164, 166 are thus provided to ensure that heat dissipation from the semiconductor dies 108, 110 is facilitated, thereby ensuring better performance of the RF circuitry formed with the semiconductor dies 108, 110.

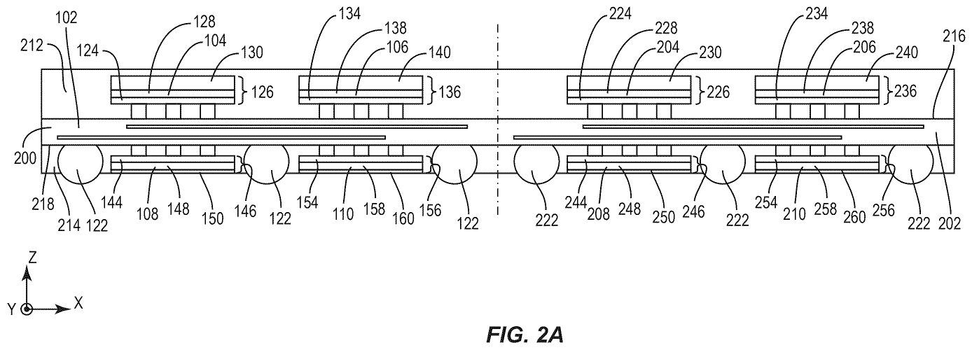

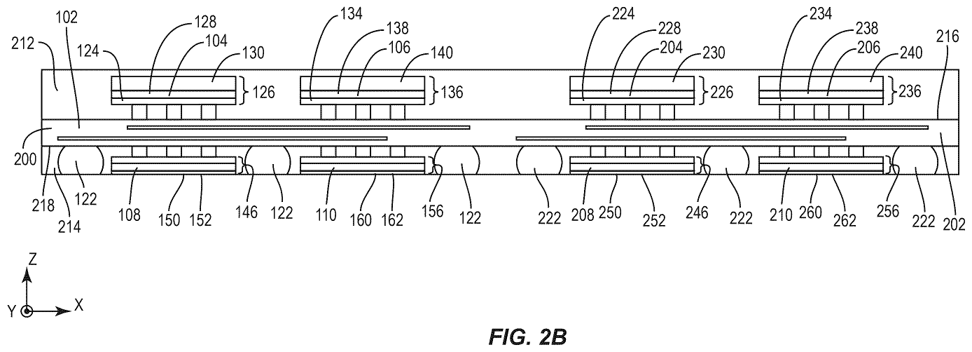

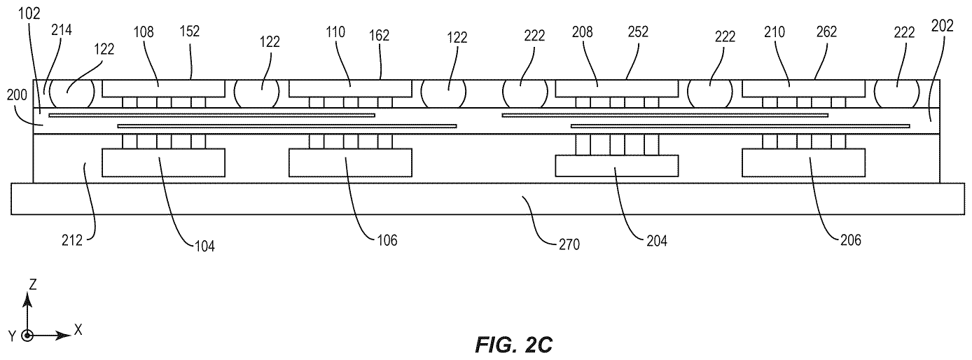

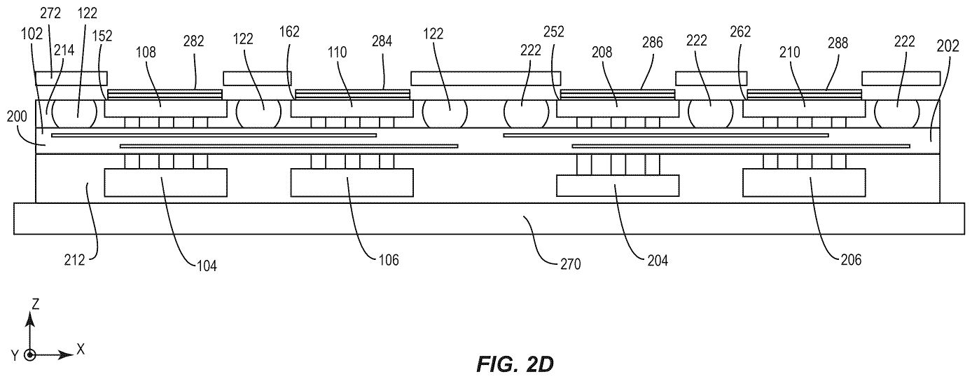

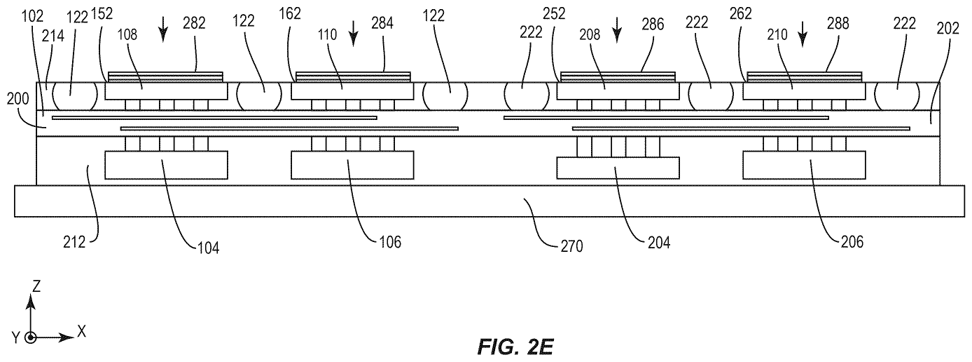

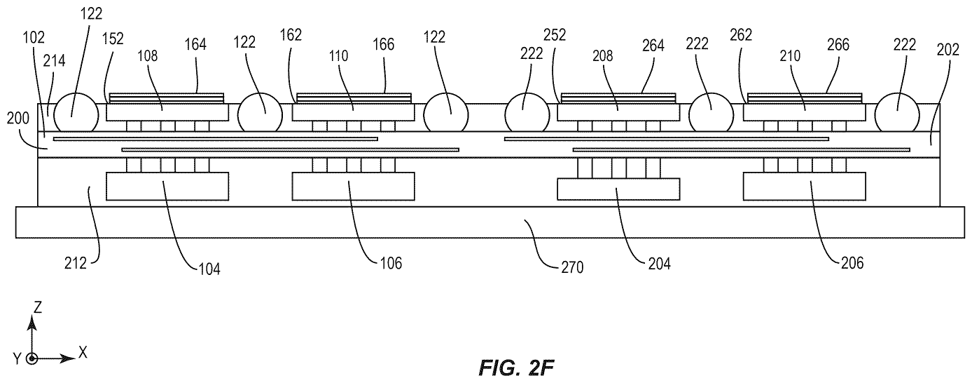

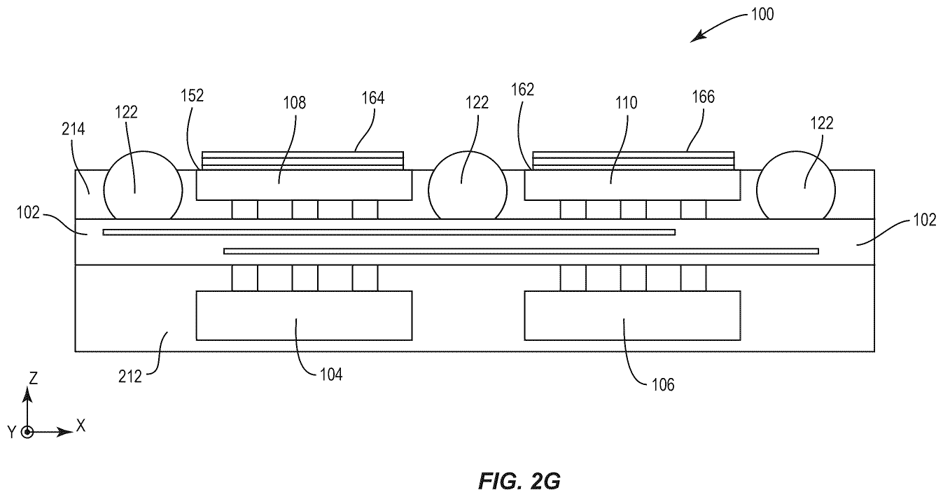

FIGS. 2A-2G illustrate procedures for manufacturing the RF package 100 shown in FIG. 1A and FIG. 1B, in accordance with some embodiments.

It should be understood that other types of RF packages may be formed based on the concepts discussed in the procedures described by FIGS. 2A-2G.

At FIG. 2A, a meta package substrate 200 defining an upper side 216 and a lower side 218 is provided. The term “meta” refers to the fact that the meta package substrate 200 is to be used to form multiple different RF packages, such as the RF package 100 shown in FIG. 1A and FIG. 1B. Thus, the meta package substrate 200 includes the package substrate 102 described above with respect to FIG. 1A and FIG. 1B that is to be used to form the RF package 100. However, the package substrate 102 has not been individuated yet and thus is integrated to and attached to another portion of the meta package substrate 200 that will be used to form another package substrate 202 for a different RF package. In this embodiment, the package substrate 202 has the exact same configuration as the package substrate 102. In other embodiments, the different portions of the meta package substrate 200 may have different configurations in order to form different types of RF packages.

The meta package substrate 200 has an upper side 216 and a lower side 218. The semiconductor die 104, the semiconductor die 106, a semiconductor die 204, and a semiconductor die 206 are mounted to the upper side 216, and the semiconductor die 108, the semiconductor die 110, a semiconductor die 208, and a semiconductor die 210 are mounted to the lower side 218. An overmold 212 entirely covers the upper side 216 and entirely covers the semiconductor die 104, the semiconductor die 106, the semiconductor die 204, and the semiconductor die 206. An overmold 214 entirely covers the lower side 218 and entirely covers the semiconductor die 108, the semiconductor die 110, the semiconductor die 208, and the semiconductor die 210. Furthermore, the solder balls 122 and solder balls 222 are attached to the lower side 218.

It should be noted that the semiconductor die 204 has a BEOL portion 224 and a semiconductor substrate 226 that includes an FEOL portion 228 and a handle 230 like that of the semiconductor die 104. Furthermore, the semiconductor die 206 has a BEOL portion 234 and a semiconductor substrate 236 that includes an FEOL portion 238 and a handle 240. The semiconductor die 208 has a BEOL portion 244 and a semiconductor substrate 246 that includes an FEOL portion 248 and a handle 250. Finally, the semiconductor die 210 has a BEOL portion 254 and a semiconductor substrate 256 that includes an FEOL portion 258 and a handle 260.

At FIG. 2B, grinding through the overmold 214 is performed to thin the handle 150, to thin the handle 160, to thin the handle 250, and to thin the handle 260. In this manner, the substrate surface 152 of the handle 150, the substrate surface 162 of the handle 160, a substrate surface 252 of the handle 250, and a substrate surface 262 of the handle 260 are exposed through the overmold 214 after the grinding. The grinding also grinds the tops of the solder balls 122, 222.

At FIG. 2C, the meta package substrate 200 is flipped and the overmold 212 is placed on a carrier 270. In this manner, the substrate surface 152, the substrate surface 162, the substrate surface 252, and the substrate surface 262 are exposed. The substrate surface 152, the substrate surface 162, the surface 252, and the surface 262 are wash-cleaned and dried to remove particles and moisture. In some embodiments, the substrate surface 152, the substrate surface 162, the substrate surface 252, and the substrate surface 262 are plasma cleaned/etched to modify surface topography of the substrate surface 152, the substrate surface 162, the substrate surface 252, and the substrate surface 262.

At FIG. 2D, a mask 272 is applied on the overmold 214 after grinding. The exposed substrate surface 152, the exposed substrate surface 162, the exposed surface 252, and the exposed surface 262 are exposed through apertures in the mask 272. Additionally, an metallization paste 282 is applied to the exposed substrate surface 152, an metallization paste 284 is applied to the exposed substrate surface 162, an metallization paste 286 is applied to the exposed surface 252, and an metallization paste 288 is applied to the exposed surface 262. The metallization pastes 282, 284, 286, 288 may each be a silver paste. In other embodiments, one or more of the metallization pastes 282, 284, 286, 288 may be formed with a different metal other than silver (e.g., tungsten, molybdenum, gold, tin, copper, aluminum, nickel, sinterable alloys). In some embodiments, a screen-printing process is used with a stencil to apply the metallization paste 282, the metallization paste 284, the metallization paste 286, and the metallization paste 288 onto the exposed substrate surface 152, the exposed substrate surface 162, the exposed surface 252, and the exposed surface 262. The metallization paste 284 and the metallization paste 288 are patterned in different shapes/arrays (see FIG. 1B). In some embodiments, a thickness of the stencil can be 50 μm or less, in order to make the metallization paste 282, the metallization paste 284, the metallization paste 286, and the metallization paste 288 each thinner than the standoff height (50 μm) of solder balls 122, 222 after curing (see FIG. 2F). The metallization pastes 282, 284, 286, 288 may each be formed from a sinterable epoxy.

At FIG. 2E, the mask 272 (see FIG. 2D) is removed.

At FIG. 2F, the metallization paste 282 (see FIG. 2D), the metallization paste 284 (see FIG. 2D), the metallization paste 286 (see FIG. 2D), and the metallization paste 288 (see FIG. 2D) are cured to form the sintering metallization layer 164 on the exposed substrate surface 152, the sintering metallization layer 166 on the exposed substrate surface 162, a sintering metallization layer 264 on the exposed surface 252, and a sintering metallization layer 266 on the exposed surface 262. The sintering metallization layer 164 is exposed through the overmold 214, the sintering metallization layer 166 is exposed through the overmold 214, the sintering metallization layer 264 is exposed through the overmold 214, and the sintering metallization layer 266 is exposed through the overmold 214. The curing process can be heat curing (e.g., cure the material in a heating oven) or light amplification by the stimulated emission of radiation (LASER) curing (e.g., neodymium-doped yttrium aluminum garnet (Nd: YAG) LASER with wavelength 1064 nm). Note that the curing, or another heating process (e.g. reflow soldering the whole assembly in a heating furnace), also reshapes the solder balls 122, 222 to obtain the desired standoff height for the solder balls in PCB assembly.

At FIG. 2G, the meta package substrate 200 (see FIG. 2A) is diced to individuate into different RF packages, such as the RF package 100.

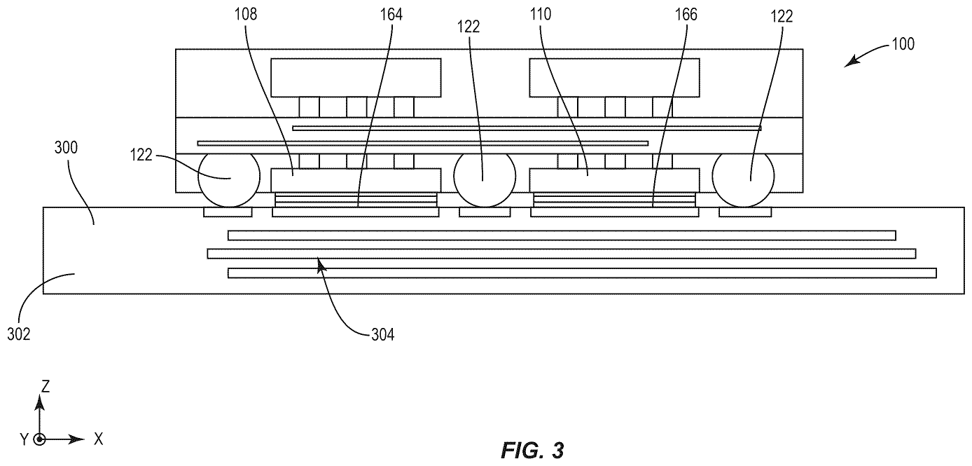

FIG. 3 is the RF package 100 mounted to a PCB 300, in accordance with some embodiments.

Thus, after the RF package 100 is individuated, the RF package 100 may be mounted to the PCB 300. The PCB 300 is formed from a laminate 302 and a metallic structure 304. The solder balls 122 are soldered to connect to the metallic structure 304. Additionally, the sintering metallization layers 164, 166 are soldered to the metallic structure 304. In this manner, heat from the semiconductor dies 108, 110 dissipates into the PCB 300, thereby allowing for better heat dissipation in the RF package 100.

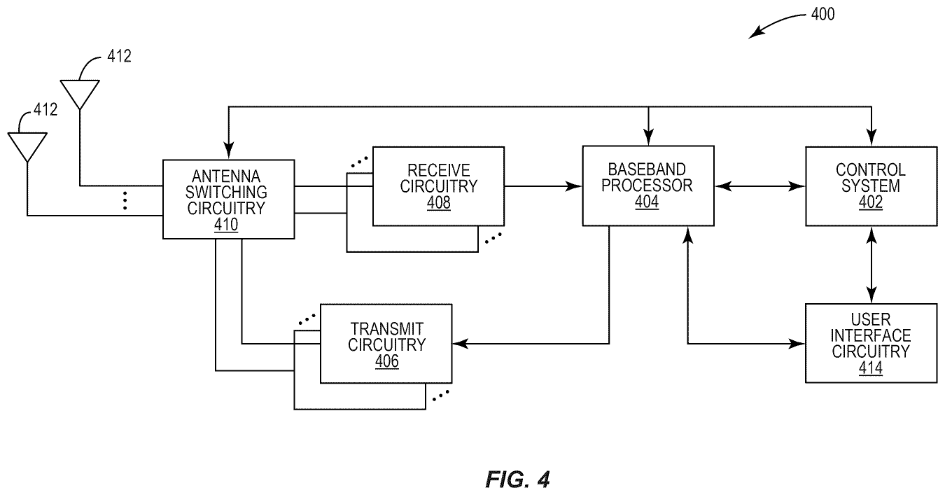

FIG. 4 is a user element 400, in accordance with some embodiments.

With reference to FIG. 4, the concepts described above may be implemented in various types of user elements 400, such as mobile terminals, smart watches, tablets, computers, navigation devices, access points, and like wireless communication devices that support wireless communications such as cellular, wireless local area network (WLAN), Bluetooth, and near-field communications. The user element 400 generally includes a control system 402, a baseband processor 404, transmit circuitry 406, receive circuitry 408, antenna switching circuitry 410, multiple antennas 412, and user interface circuitry 414. In a non-limiting example, the control system 402 may be a field-programmable gate array (FPGA) or an application-specific integrated circuit (ASIC). In this regard, the control system 402 may include at least a microprocessor, an embedded memory circuit, and a communication bus interface. The receive circuitry 408 receives radio frequency signals via the antennas 412 and through the antenna switching circuitry 410 from one or more base stations. A low-noise amplifier and a filter cooperate to amplify and remove broadband interference from the received signal for processing. Downconversion and digitization circuitry (not shown) then downconverts the filtered, received signal to an intermediate or baseband frequency signal, which is then digitized into one or more digital streams using an analog-to-digital converter (ADC).

The baseband processor 404 processes the digitized received signal to extract the information or data bits conveyed in the received signal. This processing typically comprises demodulation, decoding, and error correction operations, as will be discussed on greater detail below. The baseband processor 404 is generally implemented in one or more digital signal processors (DSPs) and application-specific integrated circuits (ASICs).

For transmission, the baseband processor 404 receives digitized data, which may represent voice, data, or control information, from the control system 402, which it encodes for transmission. The encoded data is output to the transmit circuitry 406, where a digital-to-analog converter (DAC) converts the digitally encoded data into an analog signal and a modulator modulates the analog signal onto a carrier signal that is at a desired transmit frequency or frequencies. A power amplifier amplifies the modulated carrier signal to a level appropriate for transmission and delivers the modulated carrier signal to the antennas 412 through the antenna switching circuitry 410. The multiple antennas 412 and the replicated transmit circuitry 406 and receive circuitry 408 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

What is claimed is:

1. A radio frequency (RF) package, comprising:
a package substrate having a side;
a semiconductor die mounted to the side of the package substrate, the semiconductor die comprising a semiconductor substrate, wherein the semiconductor substrate defines a substrate surface;
an overmold that covers the side of the package substrate, wherein the substrate surface of the semiconductor substrate is exposed through the overmold;
a sintering metallization layer attached to the substrate surface of the semiconductor substrate is exposed through the overmold.

2. The RF package of claim 1, further comprising:
a plurality of solder balls attached to the side of the package substrate, wherein the plurality of solder balls is exposed through the overmold.

3. The RF package of claim 1, wherein the sintering metallization layer is contiguous.

4. The RF package of claim 1, wherein the sintering metallization layer is patterned into sintering metallization patches.

5. The RF package of claim 4, wherein the sintering metallization patches are positioned in an array.

6. The RF package of claim 1, wherein the sintering metallization layer comprises a sintering silver layer.

7. The RF package of claim 1, wherein the side of the package substrate is a first side of the package substrate, the overmold is a first overmold, and the semiconductor die is a first semiconductor die, and wherein:
the RF package further comprises a second semiconductor die and a second overmold;
the package substrate defines a second side opposite the first side;
the second semiconductor die is mounted to the second side of the package substrate; and
the second overmold covers the second side of the package substrate.

8. A method of manufacturing an RF package, comprising:
providing a package substrate defining a side, wherein a semiconductor die is attached to the side, the semiconductor die has a semiconductor substrate, wherein the semiconductor substrate defines a substrate surface, and an overmold covers the side and the semiconductor die including the semiconductor substrate;
grinding through the overmold and the semiconductor substrate to thin the semiconductor substrate such that a surface of the semiconductor die is exposed through the overmold after the grinding;
applying a metallization paste to the exposed surface of the semiconductor die;
curing the metallization paste to form a sintering metallization layer attached to the substrate surface of the semiconductor substrate exposed through the overmold.

9. The method of claim 8, further comprising:
applying a mask on the overmold after grinding, wherein the exposed surface of the semiconductor die is also exposed through the mask.

10. The method of claim 8, wherein apply the metallization paste to the exposed surface of the semiconductor die further comprises patterning the metallization paste.

11. The method of claim 10, wherein the metallization paste is patterned into patches.

12. The method of claim 11, wherein the patches are positioned in an array.

13. The method of claim 9, further comprising:
a plurality of solder balls are attached to the side of the package substrate, wherein the plurality of solder balls are exposed through the overmold.

14. The RF package of claim 9, wherein the side of the substrate package is a first side of the substrate package, the overmold is a first overmold, and the semiconductor die is a first semiconductor die, and wherein:
the RF package further comprises a second semiconductor die and a second overmold;
the package substrate defines a second side opposite the first side;
the second semiconductor die is mounted to the second side of the package substrate; and
the second overmold covers the second side of the package substrate.

15. The RF package of claim 1, wherein the metallization paste comprises a silver paste.

16. A user element that includes a radio frequency (RF) package comprising:
a package substrate having a side;
a semiconductor die mounted to the side of the package substrate, the semiconductor die comprising a semiconductor substrate, wherein the semiconductor substrate defines a substrate surface;
an overmold that covers the side of the package substrate, wherein the substrate surface of the semiconductor substrate is exposed through the overmold; and
a sintering metallization layer attached to the substrate surface of the semiconductor substrate is exposed through the overmold.

17. The user element of claim 16, wherein RF package further comprises:
a plurality of solder balls are attached to the side of the package substrate, wherein the plurality of solder balls is exposed through the overmold.

18. The user element of claim 16, wherein the sintering metallization layer is contiguous.

19. The user element of claim 16, wherein the sintering metallization layer is patterned into sintering metallization patches.

20. The user element of claim 19, wherein the sintering metallization patches are positioned in an array.
